(19) United States
(12) Patent Application Publication
(10) Pub. No.: US 2011/0139213 A1
(43) Pub. Date: Jun. 16, 2011

(54) PHOTOVOLTAIC SYSTEM AND BOOST CONVERTER THEREOF

(75) Inventor: Chun-Hsien LEE, Changhua County (TW)

(73) Assignee: Du Pont Apollo Limited, Hong Kong (HK)

(21) Appl. No.: 12/961,499

(22) Filed: Dec. 7, 2010

Related U.S. Application Data
(60) Provisional application No. 61/285,780, filed on Dec. 11, 2009.

(51) Int. Cl. H01L 31/042; G05F 1/46

(52) U.S. Cl. 136/244; 323/282

(57) ABSTRACT

A photovoltaic system is disclosed herein, which includes a blocking diode, a string of photovoltaic modules, a boost converter and a controller. The photovoltaic modules are connected in series with the blocking diode. A voltage input terminal of the boost converter is connected to an anode of the blocking diode, and a voltage output terminal of the boost converter is connected to a cathode of the blocking diode. In use, the controller can drive the boost converter when the blocking diode is cut off.

### RELATED APPLICATIONS

This application claims priority to U.S. Provisional Application Ser. No. 61/285,780, filed Dec. 11, 2009, which is herein incorporated by reference.

### BACKGROUND

1. Technical Field

The present disclosure relates to a photoelectric device, and more particularly, a photovoltaic system.

2. Description of Related Art

Energy is the source power of all economic activities and thus is highly relative to the economic advancement. For the time being, energy sources include fossil energies such as petroleum, natural gas, and coal, nuclear power, waterpower, terrestrial heat and solar energy. Among the above-mentioned energy sources, fossil energies are the most widely used energy with nuclear power being in second place, whereas the others are much less commonly used. However, upon combustion, fossil energies produce greenhouse gas such as carbon dioxides, nitrogen oxides, sulfur oxides, and hydrocarbons that are detrimental to the environment. Hence, how to reduce greenhouse gas emission has become a major international issue.

A solar cell is a device that converts the energy of sunlight directly into electricity by the photovoltaic effect. Sometimes the term solar cell is reserved for devices intended specifically to capture energy from sunlight, while the term photovoltaic cell is used when the light source is unspecified. Assemblies of cells are used to make solar panels, solar modules, or photovoltaic arrays. Photovoltaic is the field of technology and research related to the application of solar cells in producing electricity for practical use. The energy generated this way is an example of solar energy.

### SUMMARY

The following presents a simplified summary of the disclosure in order to provide a basic understanding to the reader. This summary is not an extensive overview of the disclosure and it does not identify key/critical elements of the present invention or delineate the scope of the present invention. Its sole purpose is to present some concepts disclosed herein in a simplified form as a prelude to the more detailed description that is presented later.

According to one embodiment of the present invention, a photovoltaic system includes a blocking diode, a string of photovoltaic modules, a boost converter and a controller. The photovoltaic modules are connected in series with the blocking diode. A voltage input terminal of the boost converter is connected to an anode of the blocking diode, and a voltage output terminal of the boost converter is connected to a cathode of the blocking diode. In use, the controller can drive the boost converter when the blocking diode is cut off.

According to another embodiment of the present invention, a boost converter includes a controlled switch, a diode, an inductor and a controller. An anode of the diode is connected to the controlled switch, and a cathode of the diode configured to serve as a voltage output terminal connected to a cathode of a blocking diode, wherein the blocking diode is connected in series with a string of photovoltaic modules. One end of the inductor is connected to the anode of the diode, and another end of the inductor is configured to serve as a voltage input terminal connected to a cathode of the blocking diode. In use, the controller can provide a pulse width modulation signal to control the controlled switch when the blocking diode is cut off.

Many of the attendant features will be more readily appreciated, as the same becomes better understood by reference to the following detailed description considered in connection with the accompanying drawings.

### BRIEF DESCRIPTION OF THE DRAWINGS

The present description will be better understood from the following detailed description read in light of the accompanying drawing, wherein:

FIG. 1 is a schematic diagram illustrating a photovoltaic system according to one or more embodiments of the present invention.

### DETAILED DESCRIPTION

In the following detailed description, for purposes of explanation, numerous specific details are set forth in order to attain a thorough understanding of the disclosed embodiments. It will be apparent, however, that one or more embodiments may be practiced without these specific details. In other instances, well-known structures and devices are schematically shown in order to simplify the drawing.

As used in the description herein and throughout the claims that follow, the meaning of “a”, “an”, and “the” includes reference to the plural unless the context clearly dictates otherwise. Also, as used in the description herein and throughout the claims that follow, the terms “comprise or comprising”, “include or including”, “have or having”, “contain or containing” and the like are to be understood to be open-ended, i.e., to mean including but not limited to. As used in the description herein and throughout the claims that follow, the meaning of “in” includes “in” and “on” unless the context clearly dictates otherwise.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

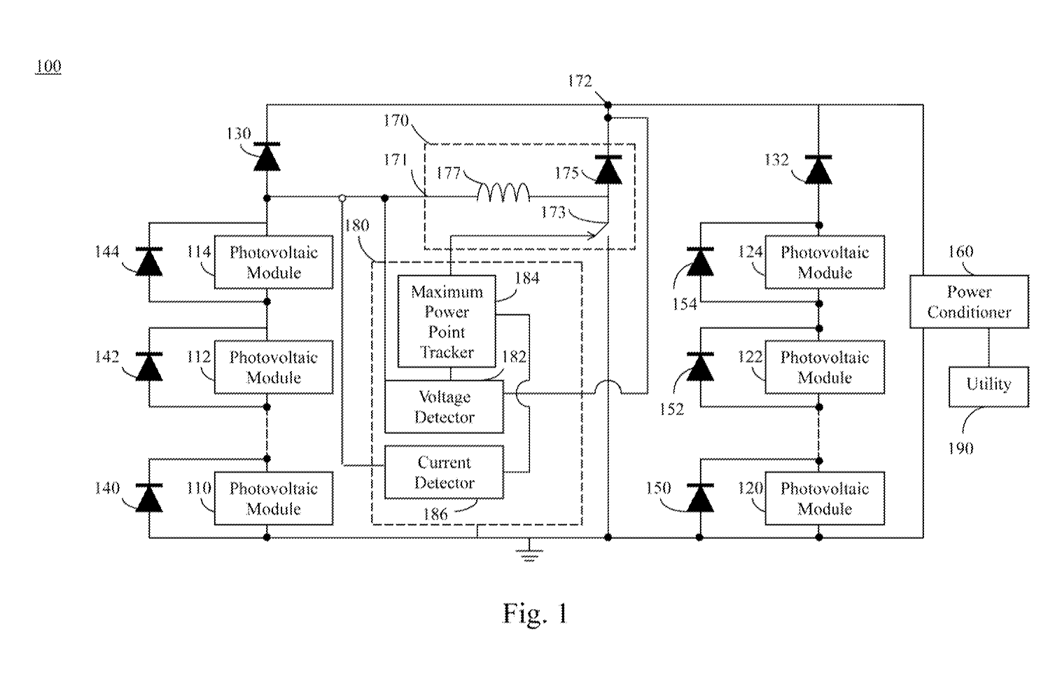

As shown in FIG. 1, the photovoltaic system 100 includes a photovoltaic (PV) array which is a linked collection of photovoltaic modules 110, 112, 114, 120, 122 and 124, which are in turn made of multiple interconnected solar cells. The cells convert solar energy into direct current electricity via the photovoltaic effect. The power that one photovoltaic module can produce is seldom enough to meet requirements of a home or a business, so the photovoltaic modules are linked together to form an array. The photovoltaic modules in the PV array are usually first connected in series to obtain the desired voltage, such as a string of the photovoltaic modules 110, 112 and 114 and another string of the photovoltaic modules 120, 122 and 124; the individual strings are then connected in parallel to allow the system to produce more current.

The string of the photovoltaic modules 110, 112 and 114 are connected in series with a blocking diode 130; similarly, the string of the photovoltaic modules 120, 122 and 124 are connected in series with a blocking diode 132. The blocking diode 130 or 132 is to protect its photovoltaic string from a reverse power flow. Thus, the blocking diode disconnects the photovoltaic string form the rest of the photovoltaic strings when the voltage of the string is below the optimal system voltage, for example, one or more photovoltaic modules of the photovoltaic string failed or were hidden from light by cloud or the like, so as to avoid the system voltage drop.

Moreover, each of the photovoltaic modules 110, 112, 114, 120, 122 and 124 in the photovoltaic system 100 includes bypass diodes 140, 142, 144, 150, 152 and 154 disposed therein, wherein each of the bypass diodes 140, 142, 144, 150, 152 and 154 is connected with each of the photovoltaic modules 110, 112, 114, 120, 122 and 124 in parallel. Thus, for example, if the photovoltaic module 112 failed or was hidden from light, the photovoltaic module 110 is electrically coupled to the photovoltaic module 114 via the bypass diode 142, so that the photovoltaic module 110 and 114 still supply power.

It should be appreciated that foresaid six photovoltaic modules illustrated in FIG. 1 are only examples and should not be regarded as limitations of the present invention. Those with ordinary skill in the art may choose the amount of photovoltaic modules depending on the desired application.

As shown in FIG. 1, a power conditioner 160 is connected with the plurality of the photovoltaic arrays. In the photovoltaic system 100, the power conditioner 160 is connected in parallel to the blocking diode 130 and the string of the photovoltaic modules 110, 112 and 114; similarly, the power conditioner 160 is connected in parallel to the blocking diode 132 and the string of the photovoltaic modules 120, 122 and 124.

For example, output power from the plurality of the strings photovoltaic modules are put together and supplied to the power conditioner 160. The power conditioner 160 may be an inverter to convert the direct current (DC) power produced by the photovoltaic modules into alternating current power. The alternating current power is then supplied to a utility 190 or other loads. Therefore, the maximum output power that is the sum of the maximum power of each photovoltaic string is supplied to the utility 190. Moreover, the power conditioner 160 may be a DC-DC converter, a secondary battery or the like according to the demands. Said examples of the power conditioner 160 are merely provided for illustration and exemplification, but are not used to limit the scope of the present invention. Those with ordinary skill in the art may design the power conditioner 160 depending on the desired application.

The photovoltaic system 100 includes a boost converter 170 and a controller 180. In this embodiment, the boost converter 170 is connected to or coupled with the controller 180. In an alternative embodiment, the controller 180 can be configured in the boost converter 170.

The boost converter 170 has a voltage input terminal 171 and a voltage output terminal 172. The voltage input terminal 171 is connected to an anode of the blocking diode 130, and the voltage output terminal 172 is connected to a cathode of the blocking diode 130. In use, the controller 180 can drive the boost converter 170 when the blocking diode 130 is disconnected. Thus, the string of the photovoltaic modules 110, 112 and 114 can supply power through boost converter 170 even though one or more photovoltaic modules failed or were hidden from light.

It should be noted that the single boost converter 170 is connected to the blocking diode 130 for illustrative purposes only; in one or more embodiments, a plurality of boost converters can be connected to the blocking diodes respectively.

The boost converter 170 includes a controlled switch 173, a diode 175 and an inductor 177. An anode of the diode 175 is connected to the controlled switch 173, and a cathode of the diode 175 is configured to serve as the voltage output terminal 172. One end of the inductor 177 is connected to the anode of the diode 175, and another end of the inductor 177 is configured to serve as the voltage input terminal 171. For example, the inductor 177 is an inductance coil; the controlled switch is a metal oxide semiconductor, a bipolar junction transistor or the like, so as to facilitate implementations.

Alternatively, a flyback converter or forward converter may replace the boost converter 170. The use of the boost converter 170 or the other is a design choice representing cost vs. efficiency tradeoffs. In practice, the boost converter 170 is implemented to achieve low cost and high efficiency.

In this embodiment, the controller 180 can provide a pulse width modulation signal to control the controlled switch when the blocking diode 130 is disconnected. The controller 180 includes a voltage detector 182 and a maximum power point tracker 184. The voltage detector 182 is connected to the anode and cathode of the blocking diode 130. In use, the voltage detector 182 can detect a forward voltage across the blocking diode 130. The maximum power point tracker 184 is configured to send a pulse width modulation signal to the controlled switch 173 for maximizing power at the voltage output terminal 172 when the forward voltage across the blocking diode 130 is lower than a cut-in voltage of the blocking diode 130. In this way, the boost converter 170 can perform the function of Maximum Power Point Tracking (MPPT), so as to maintain the maximum power for the system.

In optional, the controller 180 includes a current detector 186. In use, the current detector 186 can detect electric current through the blocking diode 130. The maximum power point tracker 184 is configured to send a pulse width modulation signal to the controlled switch 173 for maximizing power at the voltage output terminal 172 when the electric current detected by the current detector 186 is lower than a predetermined current. Alternatively or additionally, when the electric current detected by the current detector 186 is lower than the predetermined current and when the forward voltage across the blocking diode 130 is lower than the cut-in voltage of the blocking diode 130, the maximum power point tracker 184 sends the pulse width modulation signal to the controlled switch 173 for maximizing power at the voltage output terminal 172.

For example, the voltage detector 182 may be a voltage detector circuit, a voltage-detecting device, a voltage sensing circuit, a voltage-measuring device, a voltmeter or the like. Similarly, the current detector 186 may be a current detecting circuit, a current detecting apparatus, a galvanometer or the like.

It will be understood that the above description of embodiments is given by way of example only and that those with ordinary skill in the art may make various modifications. The above specification, examples and data provide a complete description of the structure and use of exemplary embodiments of the invention. Although various embodiments of the invention have been described above with a certain degree of particularity, or with reference to one or more individual embodiments, those with ordinary skill in the art could make numerous alterations to the disclosed embodiments without departing from the spirit or scope of this invention.

Any element in a claim that does not explicitly state “means for” performing a specified function, or “step for” performing a specific function, is not to be interpreted as a “means” or “step” clause as specified in 35 U.S.C. §112, 6th paragraph. In particular, the use of “step of” in the claims herein is not intended to invoke the provisions of 35 U.S.C. §112, 6th paragraph.

What is claimed is:

1. A photovoltaic system comprising:
a blocking diode;
a plurality of photovoltaic modules connected in series with the blocking diode; and
a boost converter having a voltage input terminal connected to an anode of the blocking diode and a voltage output terminal connected to a cathode of the blocking diode; and
a controller for driving the boost converter when the blocking diode is cut off.

2. The photovoltaic system of claim 1, wherein the boost converter comprises:
a controlled switch;
a diode having an anode connected to the controlled switch and a cathode configured to serve as the voltage output terminal; and
an inductor having one end connected to the anode of the diode and another end configured to serve as the voltage input terminal.

3. The photovoltaic system of claim 2, wherein the inductor is an inductance coil.

4. The photovoltaic system of claim 2, wherein the controlled switch is a metal oxide semiconductor or a bipolar junction transistor.

5. The photovoltaic system of claim 1, wherein the controller comprises:
a voltage detector for detecting a forward voltage across the blocking diode potential difference between the anode and the cathode of the blocking diode; and
a maximum power point tracker configured to send a pulse width modulation signal to the controlled switch for maximizing power at the voltage output terminal when the forward voltage the potential difference is lower than a cut-in voltage of the blocking diode.

6. The photovoltaic system of claim 1, wherein the controller comprises:
a current detector for detecting electric current through the blocking diode; and
a maximum power point tracker configured to send a pulse width modulation signal to the controlled switch for maximizing power at the voltage output terminal when the electric current is lower than a predetermined current.

7. The photovoltaic system of claim 1, further comprising:
a power conditioner connected in parallel to the blocking diode and the photovoltaic modules.

8. The photovoltaic system of claim 1, further comprising:
a plurality of bypass diodes, wherein each of the bypass diodes is connected with each of the photovoltaic modules in parallel.

9. A photovoltaic system comprising:
a blocking diode;
a plurality of photovoltaic modules connected in series with the blocking diode; and
a boost converter having a voltage input terminal connected to an anode of the blocking diode and a voltage output terminal connected to a cathode of the blocking diode; and
means for driving the boost converter when the blocking diode is cut off.

10. The photovoltaic system of claim 1, wherein the boost converter comprises:
a controlled switch;
a diode having an anode connected to the controlled switch and a cathode configured to serve as the voltage output terminal; and
an inductor having one end connected to the anode of the diode and another end configured to serve as the voltage input terminal.

11. The photovoltaic system of claim 10, wherein the inductor is an inductance coil.

12. The photovoltaic system of claim 10, wherein the controlled switch is a metal oxide semiconductor or a bipolar junction transistor.

13. The photovoltaic system of claim 9, wherein the means for driving the boost converter comprises:
means for detecting a forward voltage across the blocking diodepotential difference between the anode and the cathode of the blocking diode; and
means for maximizing power at the voltage output terminal when the forward voltage potential difference is lower than a cut-in voltage of the blocking diode.

14. The photovoltaic system of claim 9, wherein the controller comprises:
means for detecting electric current through the blocking diode; and
means for maximizing power at the voltage output terminal when the electric current is lower than a predetermined current.

15. The photovoltaic system of claim 9, further comprising:
a power conditioner connected in parallel to the blocking diode and the photovoltaic modules.

16. The photovoltaic system of claim 9, further comprising:
a plurality of bypass diodes, wherein each of the bypass diodes is connected with each of the photovoltaic modules in parallel.

17. A boost converter comprising:
a controlled switch;
a diode having an anode connected to the controlled switch and a cathode configured to serve as a voltage output terminal connected to a cathode of a blocking diode, wherein the blocking diode is connected in series with a string of photovoltaic modules;
a inductor having one end connected to the anode of the diode and another end configured to serve as a voltage input terminal connected to a cathode of the blocking diode; and
a controller for providing a pulse width modulation signal to control the controlled switch when the blocking diode is cut off.

18. The boost converter of claim 17, wherein the controller comprises:
a voltage detector for detecting a forward voltage across the blocking diode potential difference between the anode and the cathode of the blocking diode; and
a maximum power point tracker configured to send a pulse width modulation signal to the controlled switch for maximizing power at the voltage output terminal when the forward voltage potential difference is lower than a cut-in voltage of the blocking diode.

19. The boost converter of claim 17, wherein the controller comprises:
a current detector for detecting electric current through the blocking diode; and
a maximum power point tracker configured to send a pulse width modulation signal to the controlled switch for maximizing power at the voltage output terminal when the electric current is lower than a predetermined current.

20. The boost converter of claim 17, wherein the inductor is an inductance coil, and the controlled switch is a metal oxide semiconductor or a bipolar junction transistor.
